(19) United States
(12) Patent Application Publication
(10) Pub. No.: US 2011/0231122 A1
(43) Pub. Date: Sep. 22, 2011

(54) METHOD AND SYSTEM FOR DETERMINING THE KIND OF A BATTERY

(75) Inventors: Antoni Ferré Fàbregas, Valls (ES); David Gamez Alari, Valls (ES); Stanislav Lincer, Valls (ES)

(73) Assignee: LEAR CORPORATION, Dearborn, MI (US)

(21) Appl. No.: 12/724,972

(22) Filed: Mar. 16, 2010

(51) Int. Cl. G01R 31/36; G06F 19/00

(52) U.S. Cl. 702/63

(57) ABSTRACT

A method and system is disclosed for determining the kind of a battery in an automotive vehicle. Based on obtaining a set of battery parameters corresponding to the battery in the automotive vehicle, the set of battery parameters is compared to a number of predetermined sets of known battery parameters to obtain respective comparison values. Based on at least one of the comparison values, the kind of battery in the vehicle is determined to be of the same type and capacity as a known kind of battery that corresponds to one of the predetermined sets of known battery parameters.

### BACKGROUND

1. Technical Field

The present invention relates to determining parameters of a battery.

2. Background Art

An automotive vehicle typically includes a battery. However, the battery may be electrically disconnected or otherwise removed from the vehicle. For example, the battery may be electrically disconnected during service or inspection of the battery or vehicle. In another example, an old battery may be removed from the vehicle and replaced with a new battery. The new battery may be a different kind of battery from the old battery.

### SUMMARY

A method and system is provided for determining the kind of a battery in an automotive vehicle. A set of battery parameters corresponding to the battery in the automotive vehicle is obtained and compared to a number of predetermined sets of battery parameters of known kinds of batteries to obtain respective comparison values. Based on at least one of the comparison values, the kind of the battery in the vehicle is determined to be of the same kind as the known kind of battery that corresponds to the at least one of the comparison values. In turn, a characteristic of the battery in the vehicle is determined to have the same characteristic of this known kind of battery.

### BRIEF DESCRIPTION OF THE DRAWINGS

FIG. 1 is a schematic diagram illustrating a system for determining the kind of a battery in an automotive vehicle in accordance with an embodiment of the present invention; and

FIG. 2 is a flowchart diagram illustrating a method of determining the kind of a battery in an automotive vehicle in accordance with an embodiment of the present invention.

### DETAILED DESCRIPTION

Embodiments of the present invention generally comprise a method and system for determining the kind of a battery in an automotive vehicle. It may be desirable or necessary to determine the kind of the battery to facilitate proper use, operation, maintenance, service, and/or care of the battery in the vehicle. In one example, a new battery which replaces an old battery in a vehicle may have a voltage charging requirement that is different from voltage charging requirement of the old battery. Charging the new battery at too high of a voltage may degrade or damage the new battery. Thus, it may be desirable or necessary to charge the new battery at a voltage different from the voltage corresponding to the old battery. Determining the kind of the new battery may be used to determine the required voltage for charging the new battery in the vehicle. In another example, the new battery may have a current cranking capability that is different from the current cranking capability of the old battery. Thus, it may be desirable or necessary to draw current from the new battery at a cranking level different from the cranking level of the old battery. Furthermore, it may be desirable or necessary to warn a user of the automobile vehicle that the new battery is unable to crank the vehicle, such as when the new battery is unable to deliver current at a level needed to crank the vehicle.

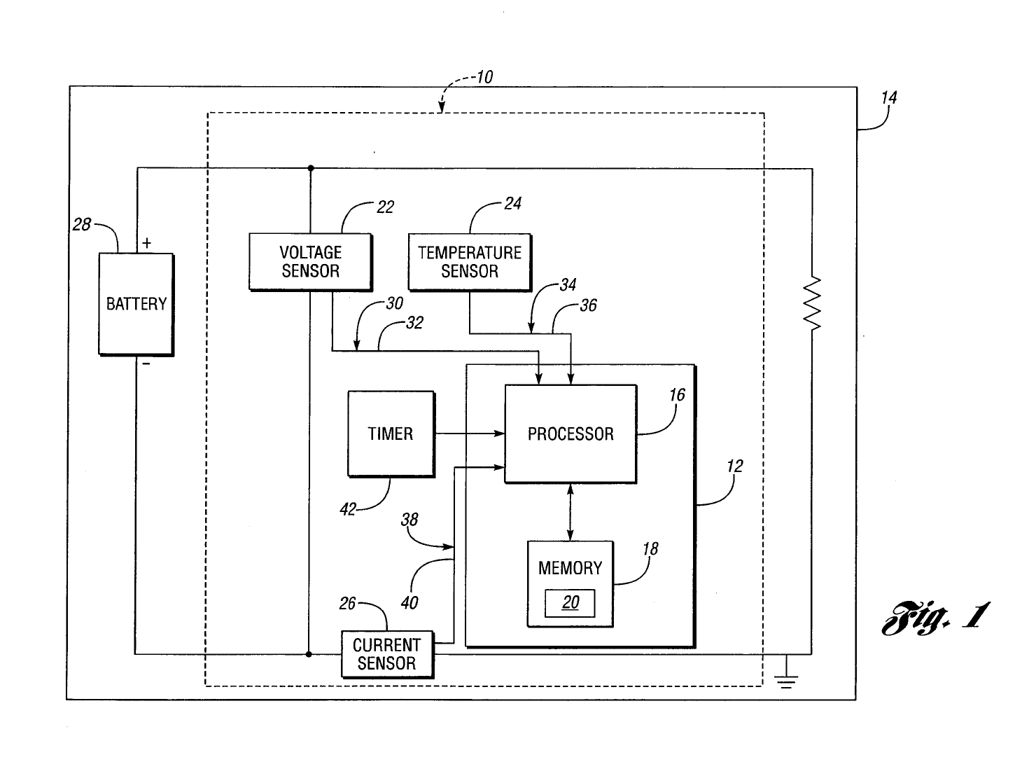

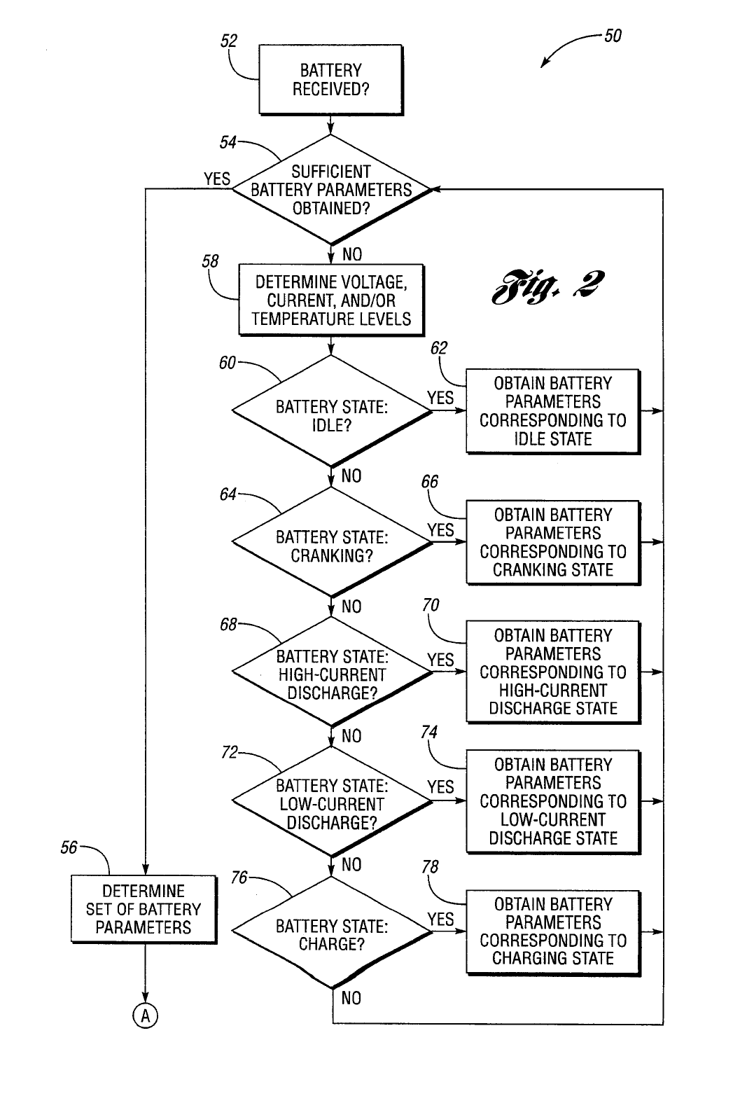

With reference to FIG. 1, a system 10 is provided for determining the kind of a battery in an automotive vehicle in accordance with an embodiment of the present invention. The system 10 includes at least one computer-based controller 12 or some other type of programmable logic device. The controller 12 may be a single hardware device, include multiple controllers in the form of multiple hardware devices, or include multiple software controllers within one or more hardware devices. For example, the controller 12 may be a battery control module (BCM) or a battery monitoring system (BMS) of an automotive vehicle 14. In another example, the controller 12 may be a vehicle system controller, a powertrain control module, the BCM, the BMS, or a combination thereof depending on the configuration of the system 10.

As shown in FIG. 1, the controller 12 includes a processor 16 and a computer-readable storage medium or memory 18. For example, the memory may be flash memory. The processor 16 operates to execute a set of software instructions 20, a computer program, and/or an algorithm of the system 10. The processor 16 may be an electronic integrated circuit or microprocessor.

The memory 18 can be part of the controller 18 as shown in FIG. 1. However, the memory 18 may be positioned in any suitable portion or portions in the vehicle 14 accessible by the controller 12. The memory 18 stores the software instructions 20. In addition to storing the software instructions 20, the memory 18 can store data or information about the various operating conditions or components in the vehicle 14 for the system 10 or to implement the method.

As illustrated in FIG. 1, the system 10 includes a voltage sensor 22, a temperature sensor 24, and a current sensor 26. The voltage sensor 22 senses voltage across a battery 28 in the vehicle 14. For example, the battery 28 may be a battery that has been electrically disconnected from the vehicle 14 or a new battery that has replaced an old battery (not shown) in the vehicle. In operation, the voltage sensor 22 obtains a voltage level across the battery 28 and generates a voltage signal 30. The voltage signal 30 is embedded or encoded with the voltage level obtained across the battery 28 either in digital or analog form. For example, the voltage level may be sensed at the positive terminal of the battery 28. The voltage signal 30 is transmitted from the voltage sensor 22 to the controller 12 along electrical communication path 32.

The temperature sensor 24 senses a temperature level of the battery 28 and generates a temperature signal 34 embedded or encoded with the temperature level of the battery 28 either in digital or analog form. For example, the temperature sensor 24 may be located near the negative terminal of the battery 28. The temperature signal 34 is transmitted from the temperature sensor 24 to the controller 12 along electrical communication path 36. Communication paths 32 and 36 may be unique paths depending on the configuration of the system 10. In addition, voltage signal 30 and temperature signal 34 may be transmitted along communication paths 32 and 36 at different times.

The current sensor 26 senses a current level flowing from or to the battery 28 and through the current sensor 26. For example, the current level may be sensed with a shunt connected to the negative terminal of the battery 28. Based on sensing the current from or to the battery 28, the current sensor 26 generates a current signal 38 for the controller 12. The current signal 38 is embedded or encoded with the current level sensed flowing from or to the battery 28 Like signals 30, 34, the current signal 38 may be either a digital or analog signal. The current signal 38 is transmitted from the current sensor 26 to the controller along electrical communication path 40. The electrical communication paths 32, 36, 38 may be wired, wireless, or a combination thereof depending on the configuration of the system 10.

As shown in FIG. 1, the controller 12 receives and processes the voltage, temperature, and current signals 30, 34, 38 to obtain various data and/or information about the battery 28. The controller 12 may receive the signals 30, 34, 38 and store the various data and/or information into the memory 18. The system 10 may receive and process the voltage, temperature, and current signals 30, 34, 38 on a periodic basis. Furthermore, the controller 12 may process the data or information either concurrently with or after receiving the data and/or information from one or more of the sensors 22, 24, 26.

As illustrated in FIG. 1, the system 10 may include a timer 42. In operation, the timer 42 initiates processing times for the processor 16 to process the voltage, temperature, and current signals 30, 34, 38 at predetermined time intervals, which may or may not overlap in time. In addition, the timer 42 may initiate when the controller 12 receives the sensor signals 30, 34, 38 from respective sensors 22, 24, 26.

The controller 12 uses the sensor signals 30, 34, 38 to obtain a set of battery parameters of the battery 28. From the set of battery parameters obtained, the controller 12 compares the set of battery parameters to predetermined sets of known battery parameters that can be stored in memory 18. The sets of known battery parameters stored in memory 18 respectively correspond to known kinds of batteries. For instance, one set of known battery parameters corresponds to a known first kind of battery while a second set of known battery parameters corresponds to a known second kind of battery. Each of the known batteries is of a different kind having a type and a nominal capacity. For instance, a first known battery may be a WET type of battery having a first nominal capacity while a second known battery is an AGM type of battery having a second nominal capacity. The known battery parameters can be used to identify a particular kind of battery. Based on comparing the parameters corresponding to the battery 28 and the known parameters stored in memory 18, the controller 12 determines the kind of the battery 28 in the vehicle 14. In other words, the controller 12 determines the kind of battery that the battery 28 operates like under different operating conditions.

From the kind of battery determined, the controller 12 determines one or more characteristics for the battery 28. For example, the controller 12 can determine a type of battery and a nominal capacity for the battery 28. The type of battery may be of the absorbed glass matt (AGM) type or the wet cell (WET) type. The nominal capacity of the battery 28 generally refers to an amount of electric charge that the battery 28 can store or the average electric capacity of the battery 28. In addition, once the controller 12 determines the kind of the battery 28, the controller 12 may determine the battery 28 to have other characteristics that are associated with the kind of the battery 28. The other characteristics can be nominal values that are defined by a manufacture and stored in memory 18.

To determine the kind of the battery 28 in the vehicle 14, the controller 12 processes the voltage, temperature, and current signals 30, 34, 38 to obtain the voltage, temperature, and current levels of the battery 28. From the voltage, temperature, and/or current levels, the controller 12 obtains the set of battery parameters corresponding to the battery 28 for determining its kind. For example, the controller 12 may determine a cold cranking amperes (CCA) level of the battery 28 based on a combination of the voltage, temperature, and current levels obtained from the sensors 22, 24, 26. In such an example, the CCA of the battery 28 may be defined as the maximum current the battery 28 can output within thirty seconds (30 sec) at temperature level of zero degrees Fahrenheit (0° F.) without the battery 28 dropping below a predetermined voltage level, such as 7.2 volts.

The voltage, temperature, and current levels of the battery 28 may be used as one or more of the parameters for determining the kind of battery that the battery 28 operates like in the vehicle 14. In addition, the controller 12 may filter the voltage, temperature, and current levels obtained from the sensor signals 30, 34, 38 to obtain the set of battery parameters of the battery 28 for determining its kind. For example, the controller 12 may calculate an internal temperature of the battery 28 based on the temperature level obtained from the temperature sensor 24.

The controller 12 may determine other parameters of the battery 28, such as: the CCA level, a state of charge (SOC), a state of health (SOH), state of function (SOF), an open circuit voltage, a Peukert exponent, a discharge slope, and a charge acceptance of the battery 28. The controller 12 may determine one or more of these parameters through an iterative process. The iterative process uses previously determined parameters of the battery 28 to determine additional battery parameters. For example, the open circuit voltage may be determined at different times to determine the discharge slope of the battery 28. In addition, the previously determined parameters of the battery 28 may be used to improve an estimation one or more of the additional battery parameters.

Examples of the additional battery parameters are described herein. It should be understood that the controller 12 may determine other battery parameters not described herein. Although the definitions of the additional battery parameters may vary depending on the implementation or configuration of the system 10, exemplary descriptions of the additional battery parameters are provided below.

Being a device that can store electrical energy, the battery 28 has a state of charge (SOC). The controller 12 may calculate the SOC of the battery 28 based on the amount of energy that the battery 28 can store and the amount of energy that the battery 28 currently has. Thus, the SOC of the battery 28 may represent the percentage of total charge that exists in the battery 28.

The SOH of the battery 28 indicates the degradation of the battery 28. Performance of the battery 28 may degrade over time and, therefore, the SOH of the battery 28 may decrease over time. In operation, the controller 12 SOH may compare the actual capacity of the battery 28 and the nominal capacity of the battery 28 to determine the SOH of the battery 28.

The SOF of the battery 28 indicates whether the battery 28 is sufficiently able to start the vehicle 14. For example, the SOF may be obtained based on the voltage level of the battery 28, such as the minimum voltage level for cranking, during cranking or starting of an internal combustion engine in the vehicle 14. If the voltage level is below a certain threshold, then the battery 28 is unable to start the vehicle 14. In addition, the SOF of the battery 28 can be used to indicate the internal resistance of the battery 28.

The open circuit voltage of the battery 28 at full charge is the voltage level across the battery 28 when the battery 28 is sufficiently or fully charged at a maximum level (e.g., SOC=99%). The voltage sensor 22 may sense a voltage across the battery 28 before the engine is started to obtain the open circuit voltage.

The Peukert exponent of the battery 28 indicates the reduction of the capacity of the battery 28 when the battery 28 discharges at a high current.

The discharge slope of the battery 28 indicates variation of the voltage across the battery 28 as a function of the charge in the battery 28.

Charge acceptance indicates an amount of charge that the battery 28 can accept when the battery 28 has a particular SOC.

The operation of the system 10 is further described below with reference to the method, which may be implemented through the software instructions 20 stored in memory 18.

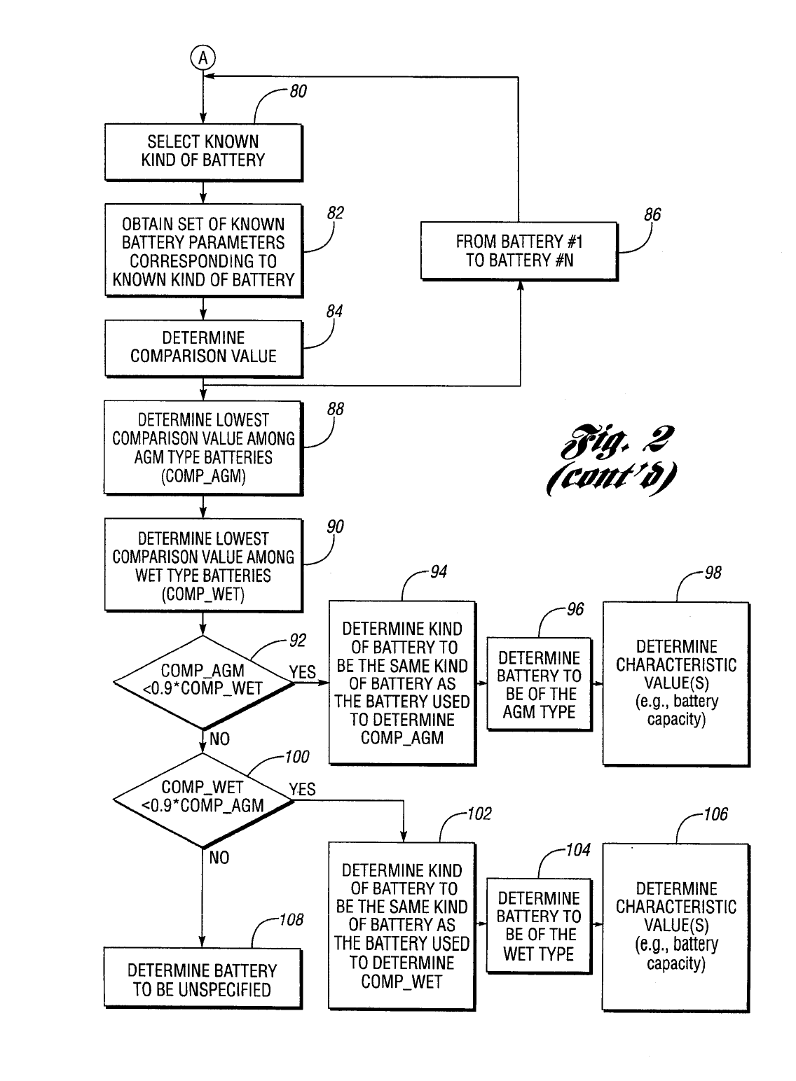

With reference to FIG. 2, a flowchart diagram 50 is provided to illustrate a method of determining the kind of a battery in an automotive vehicle in accordance with an embodiment of the present invention. From the kind of battery determined, the type of battery and the nominal capacity of the battery can be determined. Furthermore, once the controller 12 determines the kind of the battery 28, the controller 12 may determine the battery 28 to have the other characteristics associated with the kind of the battery 28, such as a nominal cold cranking amperes (CCA) value. The characteristics associated with the kind of the battery 28 can be predetermined values. The predetermined values may be provided by a manufacturer for the different kinds of batteries stored in memory 18. In addition to the steps shown in FIG. 2, a programmable logic device, such as the controller 12, may be programmed with additional steps to provide additional functionality.

Referring again to FIG. 2, the vehicle 14 and its components illustrated in FIG. 1 are referenced throughout the discussion of the method to facilitate understanding of various aspects of the method. The method of determining the kind of battery that the battery 28 operates like under different operating conditions may be implemented through a computer algorithm, machine executable code, or software instructions 20 programmed into a suitable programmable logic device(s) in the vehicle 14, such as the controller 12 of FIG. 1. The controller 12 may be a battery monitoring system (BMS) or other suitable controller in the vehicle 14. Although the various steps shown in the flowchart diagram 50 appear to occur in a chronological sequence, at least some of the steps may occur in a different order, and some steps may be performed concurrently or not at all.

At block 52 of flowchart diagram 50, a battery is received. The battery 28 of FIG. 1 is shown received by the vehicle 14. For example, the battery 28 may be received during replacement of an old battery (not shown) in the vehicle 14 with a new battery, such as the battery 28 of FIG. 1. In another example, the battery 28 may be received when the battery 28 is electrically connected to the vehicle 14, such as after service or inspection of the battery 28. Recognizing when the battery 28 is received may occur when the system 10 is energized or started for operation.

At decision block 54, it is determined whether sufficient battery parameters have been obtained. Sufficient battery parameters are needed for determining the kind of battery 28. The controller 12 can determine whether sufficient battery parameters have been obtained. Whether sufficient battery parameters have been obtained may be based on obtaining the voltage, temperature, and current levels of the battery 28 during various battery states of the battery 28, such as an idle state, a cranking state, a high-current discharge state, a low-current discharge state, a charging state, or some combination thereof. For example, the controller 12 may determine that sufficient battery parameters have been obtained when battery parameters have been obtained from the idle, cranking, high-current discharge, low-current discharge, and charging states of the battery 28.

With continuing reference to decision block 54, whether sufficient battery parameters have been obtained may be based on the controller 12 obtaining battery parameters corresponding to operation of the battery 28 during one or more of the battery states (i.e., the idle state, the cranking state, the high-current discharge state, the low-current discharge state, and the charging state). The battery parameters obtained during the battery states may include the CCA level, the SOC, the SOH, the SOF, the open circuit voltage, the Peukert exponent, the discharge slope, the charge acceptance, or a combination thereof.

Obtaining battery parameters for one of the states of the battery 28 may be obtained through one or more iterations through the respective battery state. In such an iterative process, whether sufficient battery parameters have been obtained may be based on a user of the vehicle 14 having the controller 12 exit the iterative process of obtaining the voltage, temperature, and/or current levels of the battery 28. Block 56 occurs if it is determined that sufficient battery parameters have been obtained. For example, sufficient battery parameters may be obtained when the user causes the controller 12 to exit the iterative process. However if it is determined that sufficient battery parameters have not been obtained, then block 58 can occur.

At block 56, a set of battery parameters is determined. The controller 12 may determine the set of battery parameters based any number of battery parameters, which are obtained from at least one of the blocks 58, 62, 66, 70, 74, 78 of flowchart diagram 50. Blocks 62, 66, 70, 74, 78 may occur in an order different from the order illustrated in FIG. 2 and some steps may not be performed for determining the kind of the battery 28. Likewise, block pairs 60 and 62, pairs 64 and 66, pairs 68 and 70, pairs 72 and 74, and 76 and 78 may occur in an order different from the order illustrated in FIG. 2 and some pairs may not be performed for determining the kind of the battery 28. Furthermore, other steps or pairs may be performed for determining the kind of the battery 28, such as a step of determining whether the battery 28 is out of range, damaged, et cetera. Such other steps may occur at, between, before, or after blocks 62, 66, 70, 74, 78. After other steps or pairs are performed, block 54 can occur.

With continuing reference to block 56, the battery parameters may include the voltage, temperature, and/or current levels of the battery 28 obtained during one or more of the battery states. In addition, battery parameters may include other battery parameters that the controller 12 may have calculated or looked up based on the voltage, temperature, and/or current levels of the battery 28. For example, the controller 12 may have calculated or looked up the CCA level, the SOC, the SOH, the SOF, the open circuit voltage, the Peukert exponent, the discharge slope, the charge acceptance, or a combination thereof for one or more of the battery states of the battery 28 (i.e., the idle state, the cranking state, the high-current discharge state, the low-current discharge state, and the charging state). Based on the battery parameters obtained, the controller 12 can determine the set of battery parameters for determining the kind of the battery 28.

At block 58 of flowchart diagram 50, a voltage level, a temperature level, and a current level of the battery 28 are obtained. The controller 12 may process the voltage, temperature, and current signals 30, 34, 38 from the voltage, temperature, and current sensors 22, 24, 26 to obtain the voltage, temperature, and current levels of the battery 28.

At decision block 60, it is determined whether the battery 28 is in an idle state. In the idle state, the battery 28 has current below a vehicle quiescent current threshold and is not charging from a power source, such as an engine in the vehicle 14 or a power source external to the vehicle 14. Current demand and voltage variation may be minimal during the idle state of the battery 28. The controller 12 may determine whether the battery 28 is in the idle state based on at least one of the sensor signals 30, 34, 38 or operation of the vehicle 14. If the battery 28 is determined to be in the ideal state, then block 62 can occur. However if the battery 28 is not determined to be in the ideal state, then decision block 64 can occur.

At block 62, battery parameters corresponding to the battery 28 in the idle state are obtained. The battery parameters corresponding to the battery 28 in the idle state may include the voltage, temperature, and/or current levels of the battery 28 as well as battery parameters that the controller 12 may have calculated based on the voltage, temperature, and/or current levels of the battery 28 during the idle state, such as the CCA level, the SOC, the SOH, the SOF, the open circuit voltage, the Peukert exponent, the discharge slope, the charge acceptance, or a combination thereof. Furthermore, the controller 12 may calculate the battery parameters based on historic data of the same battery parameters.

At decision block 64, it is determined whether the battery 28 is in a cranking state. In the cranking state, the battery 28 is being used in trying to start an engine in the vehicle 14. A high-current pulse and corresponding voltage decrease typically occurs during the cranking state of the battery 28. Similar to decision block 60, the controller 12 may determine whether the battery 28 is in the cranking state. If the battery 28 is determined to be in the cranking state, then block 66 can occur. However if the battery 28 is not determined to be in the cranking state, then decision block 68 can occur.

At block 66, battery parameters corresponding to the battery 28 in the cranking state are obtained. The battery parameters may include additional or fewer battery parameters obtained in block 62. Furthermore, the battery parameters corresponding to the battery 28 in the cranking state may be different from or the same as the battery parameters obtained in block 62.

At decision block 68, it is determined whether the battery 28 is in a high-current discharge state. In the high-current discharge state, the battery 28 is discharging at high current and the SOC of the battery 28 decreases. The battery 28 may discharge at a relatively constant high-current level and experience a relatively large rate of voltage decrease during the high-current discharge state of the battery 28. Similar to decision block 60, the controller 12 may determine whether the battery 28 is in the high-current discharge state. If the battery 28 is determined to be in the high-current discharge state, then block 70 can occur. However if the battery 28 is not determined to be in the high-current discharge state, then decision block 72 can occur.

At block 70, battery parameters corresponding to the battery 28 in the high-current discharge state are obtained. The battery parameters may include additional or fewer battery parameters obtained in blocks 62, 66. Furthermore, the battery parameters corresponding to the battery 28 in the high-current discharge state may be different from or the same as the battery parameters obtained in blocks 62, 66.

At decision block 72, it is determined whether the battery 28 is in a low-current discharge state. In the low-current discharge state, the battery 28 is discharging at low current and the SOC of the battery 28 decreases. The battery 28 may discharge at a relatively constant low-current level and experience a relatively low rate of voltage decrease during the low-current discharge state of the battery 28. Similar to decision block 60, the controller 12 may determine whether the battery 28 is in the low-current discharge state. If the battery 28 is determined to be in the low-current discharge state, then block 74 can occur. However if the battery 28 is not determined to be in the low-current discharge state, then decision block 76 can occur.

At block 74, battery parameters corresponding to the battery 28 in the low-current discharge state are obtained. The battery parameters may include additional or fewer battery parameters obtained in blocks 62, 66, 70. Furthermore, the battery parameters corresponding to the battery 28 in the low-current discharge state may be different from or the same as the battery parameters obtained in blocks 62, 66, 70.

At decision block 76, it is determined whether the battery 28 is in a charging state. In the charging state, the battery 28 is charging and the SOC of the battery 28 is increasing. Similar to decision block 60, the controller 12 may determine whether the battery 28 is in the charging state. If the battery 28 is determined to be in the charging state, then block 78 can occur. However if the battery 28 is not determined to be in the charging state, then decision block 54 can occur.

At block 78, battery parameters corresponding to the battery 28 in the charging state are obtained. The battery parameters may include additional or fewer battery parameters obtained in blocks 62, 66, 70, 74. Furthermore, the battery parameters corresponding to the battery 28 in the charging state may be different from or the same as the battery parameters obtained in blocks 62, 66, 70, 74.

At block 80, a known kind of battery is selected. Each known kind of battery includes a set of known battery parameters that is stored in memory 18. In addition, each known kind of battery has characteristics that indicate its expected operation, performance, or capabilities. For example, each known kind of battery can have a characteristic stored in memory 18 that indicates a type or a nominal capacity of the known battery. Thus, each known kind of battery can include a type and a nominal capacity that is stored in memory 18. The controller can access each known kind of battery stored in memory 18 to obtain the set of known battery parameters, the type, the nominal capacity, or a combination thereof that corresponds to the accessed known kind of battery.

The memory 18 of the system 10 may store multiple known kinds of batteries. For example, the memory 18 may store “N” different known kinds of batteries. The known kinds of batteries can have different operating conditions and be associated with various manufacturers, models, brands, et cetera. Each known kind of battery has a set of known battery parameters that is different from other kinds of batteries stored in memory 18. Thus, the set of known battery parameters can be used to identify a particular kind of battery.

The known battery parameters for the known kinds of batteries can be specified, programmed, or reprogrammed for the system 10. For example, battery manufactures may specify or determine the values of the known battery parameters. In another example, the memory 18 of the system 10 may be updated with the new kinds of batteries as well as battery parameters corresponding to the new kinds of batteries. Updating the memory 18 with information about the new kinds of batteries may be useful, such as when new kinds of batteries are manufactured or sold for use in the vehicle 14.

At block 82 of flowchart diagram 50, a set of known battery parameters corresponding to the known kind of battery is obtained. The controller 12 may obtain the set of known battery parameters from memory 18 based on the known kind of battery selected in block 80. For example, the set of known battery parameters may include the CCA level, the SOC, the SOH, the SOF, the open circuit voltage, the Peukert exponent, the discharge slope, and the charge acceptance for one or more battery states of the known kind of battery (e.g., an idle state, an cranking state, a high-current discharge state, a low-current discharge state, and a charging state). The set of known battery parameters obtained at block 82 are of the same class of battery parameters as the set of battery parameters determined at block 56. Thus, the set of known battery parameters stored in memory 18 may directly correspond to the set of battery parameters determined for the battery 28 in the vehicle 14.

At block 84, a comparison value is determined between the set of battery parameters determined in block 56 and the set of known battery parameters obtained in block 82. In one example, the comparison value may be determined based on calculating a deviation value (Δ), such as generally defined by the following equation:

Δ=\sqrt{(αᵢ−αₘ)²+(βᵢ−βₘ)²+ . . . +(ωᵢ−ωₘ)²}

where αₘ, βₘ, ωₘ represent the set of known battery parameters that are stored in memory 18 and correspond to the known kind of battery selected in block 80; and αᵢ, βᵢ, ωᵢ represent the set of battery parameters that were determined in block 56 and correspond to the battery 28 in the vehicle 14. In addition, the equation for calculating the deviation value (Δ) may include weighted battery parameters. Thus, some battery parameters may influence the deviation value (Δ) more than other battery parameters. For example, α may be weighted more than β or ω in the above equation. The deviation value (Δ) can be calculated for each known kind of battery. For example, the controller 12 may calculate and store a deviation value (Δ) in memory 18 for each of the “N” different known kinds of batteries.

At block 86, a number of sets of known battery parameters is obtained. The number of sets obtained from memory 18 is generally indicated by the number “N”. Block 86 illustrates that blocks 80, 82, 84 occur for each known kind of battery, such as from one to “N”. The controller 12 compares the set of battery parameters determined in block 56 to the sets of known battery parameters obtained in block 82. Based on comparing between the set of battery parameters of the battery 28 and the known parameters stored in memory 18, the controller 12 can determine a kind of battery in the vehicle 14. Once the sets of known battery parameters are obtained, block 88 can occur.

At block 88, the comparison value obtained in block 84 with the lowest value among the absorbed glass matt (AGM) type batteries is determined. The comparison value with the lowest value among the AGM type batteries may be referenced as COMP_AGM. Thus, COMP_AGM represents the lowest comparison value determined using sets of known battery parameters that correspond to AGM-type batteries. For example, the comparison value of block 88 (COMP_AGM) may be the lowest deviation value (Δ) among the set of known battery parameters corresponding to batteries of the AGM type. The controller 12 can determine the lowest deviation value (Δ_{AGMmin}) among the AGM-type batteries based on the deviation values stored in memory 18. The known kind of battery of the AGM type that is used to determine COMP_AGM may be referred to as reference battery #J.

At block 90, the comparison value obtained in block 84 with the lowest value among the wet cell (WET) type batteries is determined. The comparison value with the lowest value among the WET type batteries may be referenced as COMP_WET. Thus, COMP_WET represents the lowest comparison value determined using sets of known battery parameters that correspond to WET-type batteries. For example, the comparison value of block 90 (COMP_WET) may be the lowest deviation value (Δ) among the set of known battery parameters corresponding to batteries of the WET type. The controller 12 can determine the lowest deviation value (Δ_{WETmin}) based on the deviation values stored in memory 18. The known kind of battery of the WET type that is used to determine COMP_WET may be referred to as reference battery #K. Thus, reference batteries #J and #K can be two of the “N” different known kinds of batteries stored in memory 18 that the controller 12 can use to determine the kind of battery that the battery 28 operates like under different operating conditions.

At decision block 92, it is determined whether the comparison value of block 88 (COMP_AGM) is less than the product of the comparison value of block 90 (COMP_WET) and an AGM threshold. The AGM threshold is shown having a value of 0.9 in FIG. 2. However, the AGM threshold can be any suitable value depending on how the comparison value is determined at block 84. If COMP_AGM is less than the product of COMP_WET and the AGM threshold, then block 94 occurs. However if COMP_AGM is greater than or equal to the product of COMP_WET and the AGM threshold, then decision block 100 occurs.

At block 94, the kind of the battery 28 is determined to be the same kind of battery as the battery used to determine COMP_AGM (i.e., reference battery #J). After the controller 12 determines the kind of the battery 28, the controller 12 may determine the battery 28 to have the same one or more characteristics that are associated with reference battery #J. Thus, the controller 12 may determine the battery 28 to have the same type as reference battery #J. In addition, the controller 12 may determine the battery 28 to have the same nominal capacity as reference battery #J. Thus, the kind of battery in the system 10 may be determined to be of the AGM-type and having the same nominal capacity as the known kind of battery having the lowest deviation value (Δ_{AGMmin}) among the AGM-type batteries in memory 18. In addition, the controller 12 may determine other characteristics of the battery 28 based on the kind of battery that is determined to correspond to reference battery #J. For example, the controller 12 may determine the battery 28 to have the same nominal CCA value as stored in memory 18 for reference battery #J.

At block 96, the kind of the battery 28 is determined to be of the AGM type. The controller 12 can determine the kind of battery based on decision block 92. However, the controller 12 may determine the kind of battery based on other determinations as well. In addition, the controller 12 may store information or data indicating that the battery 28 is of the AGM type in memory 18.

At block 98, the kind of the battery 28 is determined to have one or more characteristic values equal to characteristic values corresponding to reference battery #J (i.e., the AGM-type battery with the lowest comparison value determined in block 88). For example, the kind of the battery 28 can be determined to have a nominal capacity equal to the nominal capacity corresponding to reference battery #J. The controller 12 may store information or data indicating that the battery 28 has the same nominal capacity as reference battery #J in memory 18. In addition, the controller 12 may store other characteristic values associated with reference battery #J as the characteristic values for the battery 28.

At decision block 100, it is determined whether the comparison value of block 90 (COMP_WET) is less than the product of the comparison value of block 88 (COMP_AGM) and a WET threshold. The WET threshold is shown having a value of 0.9 in FIG. 2. However, the WET threshold can be any suitable value depending on how the comparison value is determined at block 84. Furthermore, the WET threshold at decision block 100 may be different from the AGM threshold at decision block 92. For example, the AGM threshold may be 0.85 while the WET threshold may be 0.95. If COMP_WET is less than the product the WET threshold and COMP_AGM, then block 102 occurs. However if COMP_WET is greater than or equal to the product the WET threshold and COMP_AGM, then the battery 28 is unspecified and block 108 occurs.

At block 102, the kind of the battery 28 is determined to be the same kind of battery as the battery used to determine COMP_WET (i.e., reference battery #K). After the controller 12 determines the kind of the battery 28, the controller 12 may determine the battery 28 to have the same one or more characteristics that are associated with reference battery #K. Thus, the controller 12 may determine the battery 28 to have the same type as reference battery #K. In addition, the controller 12 may determine the battery 28 to have the same nominal capacity as reference battery #K. Thus, the kind of battery in the system 10 may be determined to be of the WET-type and having the same nominal capacity as the known kind of battery having the lowest deviation value (Δ_{WETmin}) among the WET-type batteries in memory 18. In addition, the controller 12 may determine other characteristics of the battery 28 based on the kind of battery that is determined to correspond to reference battery #K. For example, the controller 12 may determine the battery 28 to have the same nominal CCA value as stored in memory 18 for reference battery #K.

At block 104, the kind of the battery 28 is determined to be of the WET type. The controller 12 can determine the kind of battery based on decision block 100. However, the controller 12 may determine the kind of battery based on other determinations, such as the determination at decision block 92. In addition, the controller 12 may store information or data indicating that the battery 28 is of the WET type in memory 18.

At block 106, the kind of the battery 28 is determined to have one or more characteristic values equal to characteristic values corresponding to reference battery #K (i.e., the WET type battery with the lowest comparison value determined in block 88). For example, the kind of the battery 28 can be determined to have a nominal capacity equal to the nominal capacity corresponding to reference battery #K. The controller 12 may store information or data indicating that the battery 28 has the same nominal capacity as reference battery #K in memory 18. In addition, the controller 12 may store other characteristic values associated with reference battery #K as the characteristic values for the battery 28.

At block 108, the kind of the battery 28 is determined to be unspecified. The controller 12 may determine the battery 28 to be unspecified and therefore assign characteristic values corresponding to the worst-case battery kind. For example, the nominal capacity of the unspecified battery may be set to the lowest nominal capacity that the battery 28 may reasonable have, such as the nominal capacity of the worst-case battery kind. In such an example, the controller 12 may set the nominal capacity of the unspecified battery to a voltage value equal to the lesser nominal voltage of the WET type battery with the lowest comparison value determined in block 90 (COMP_WET) and the AGM type battery with the lowest comparison value determined in block 88 (COMP_AGM).

Determining the kind of the battery 28 may enable an Energy Management System in the vehicle 14 to adapt respective energy management algorithms to processes of the battery 28. Adapting the Energy Management System to processes of the battery 28 may facilitate proper use, operation, maintenance, service, and/or care of the battery 28. In addition, the controller 12 may generate an alert signal indicating that the kind of the battery 28 is unspecified. The alert signal may indicate that the battery 28 needs maintenance or service. Also, the alert signal may indicate that the system 10 needs to be updated with new kinds of batteries and/or new associated battery parameters.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method of determining the kind of a given battery in an automotive vehicle, the method comprising:
obtaining a first set of battery parameters corresponding to the given battery;
comparing the first set to predetermined sets of known battery parameters respectively corresponding to known batteries to obtain respective comparison values for each of the known batteries, the comparison value of each known battery indicating an amount of matching between the first set and the set of known battery parameters corresponding to the known battery, wherein each known battery has at least one characteristic; and
determining the kind of the given battery to be of the same kind as the known battery associated with the comparison value having the largest amount of matching and thereby determining a characteristic of the given battery to be same as the characteristic of the known battery.

2. The method of claim 1 wherein the characteristic includes a type, thereby determining the type of the given battery to be the same as the type of the known battery.

3. The method of claim 2 wherein the characteristic includes a capacity, thereby determining the capacity of the given battery to be the same as the capacity of the known battery.

4. The method of claim 1 wherein the characteristic includes a capacity, thereby determining the capacity of the given battery to be the same as the capacity of the known battery.

5. The method of claim 1 wherein the characteristic includes a nominal cold cranking amperes (CCA) value, thereby determining the nominal CCA value of the given battery to be the same as the nominal CCA value of the known battery.

6. The method of claim 1 further including obtaining voltage, current, and temperature levels of the given battery to obtain the first set.

7. The method of claim 6 further including obtaining the battery parameters in the first set based on the voltage, current, and temperature levels of the given battery during at least two states of the given battery.

8. The method of claim 1 wherein the battery parameters in first and predetermined sets are selected from the group consisting of a voltage level, a current level, a temperature level, a cold cranking amperes (CCA) level, a state of charge (SOC), a state of health (SOH), state of function (SOF), an open circuit voltage, a Peukert exponent, a discharge slope, and a charge acceptance.

9. The method of claim 1 further including calculating deviation values based on the first and predetermined sets of battery parameters to obtain the respective comparison values.

10. The method of claim 1 further including determining the known battery based on a pair of the comparison values, the pair corresponding to two different types of batteries.

11. The method of claim 10 further including comparing the pair of comparison values based on a threshold to determine the known battery.

12. The method of claim 1 further including obtaining the battery parameters in the first set during at least two states of the given battery.

13. The method of claim 12 wherein the states of the given battery include an idle state, a cranking state, a high-current discharge state, a low-current discharge state, and a charging state.

14. The method of claim 1 further including receiving the given battery to initiate the obtaining of the first set of battery parameters.

15. A method of determining the kind of a given battery in an automotive vehicle, the method comprising:
obtaining a first set of battery parameters corresponding to the given battery based on the voltage, current, and temperature levels of the given battery during at least two states of the given battery;
comparing the first set to predetermined sets of known battery parameters to obtain respective comparison values, the predetermined sets respectively corresponding to known batteries having at least one characteristic, and the comparison values indicating an amount of matching between the first and predetermined sets; and
determining the kind of the given battery to have the same characteristic as the known battery associated with the comparison value having the largest amount of matching and thereby determining a characteristic of the given battery to be same as the characteristic of the known battery.

16. A system for determining the kind of a given battery in an automotive vehicle, the system comprising:
a voltage sensor for generating a voltage signal indicative of a voltage level across the given battery;
a current sensor for generating a current signal indicative of a current level flowing from the given battery;
a temperature sensor for generating a temperature signal indicative of a temperature level of the given battery; and
at least one computer-based controller including a processor operable to execute software instructions, a computer memory operable to store software instructions accessible by the processor, and a set of software instructions stored in the memory
to obtain a first set of battery parameters corresponding to the given battery;
to compare the first set to predetermined sets of known battery parameters respectively corresponding to known batteries to obtain respective comparison values for each of the known batteries, the comparison value of each known battery indicating an amount of matching between the first set and the set of known battery parameters corresponding to the known battery, wherein each known battery has at least one characteristic; and
to determine the kind of the given battery to be of the same kind as the known battery associated with the comparison value having the largest amount of matching and thereby determining a characteristic of the given battery to be same as the characteristic of the known battery.

17. The system of claim 16 wherein the sensors sense the voltage, current, and temperature levels during at least two battery states of the given battery, the battery states including an idle state, a cranking state, a high-current discharge state, a low-current discharge state, and a charging state.

18. The system of claim 16 wherein the first and predetermined sets of battery parameters are selected from the group consisting of a voltage level, a current level, a temperature level, a state of charge (SOC), a state of health (SOH), state of function (SOF), an open circuit voltage, a Peukert exponent, a discharge slope, and a charge acceptance.

19. The system of claim 16 wherein the comparison values are deviation values based on the first and predetermined sets of battery parameters.

20. The system of claim 16 wherein the controller determines the known kind of battery based on a pair of the comparison values, the pair corresponding to two different types of batteries.
